(19) United States
(12) Patent Application Publication
(10) Pub. No.: US 2004/0012037 A1
(43) Pub. Date: Jan. 22, 2004

(54) Hetero-integration of semiconductor materials on silicon

(75) Inventors: Suresh Venkatesan, Austin, TX (US); Papu D. Maniar, Mesa, AZ (US)

Correspondence Address: OBLON, SPIVAK, MCCLELLAND, MAIER & NEUSTADT, P.C., 1940 DUKE STREET, ALEXANDRIA, VA, 22314, US

(73) Assignee: MOTOROLA, INC., Schaumburg, IL (US)

(21) Appl. No.: 10/197,607

(22) Filed: Jul. 18, 2002

(51) Int. Cl. H01L 31/0328

(52) U.S. Cl. 257/200; 257/616

(57) ABSTRACT

High quality gallium arsenide (GaAs) (38) is grown over a thin germanium layer (26) and co-exists with silicon (40) for hetero-integration of devices. A bonded germanium wafer of silicon (22), oxide (24), and germanium (26) is formed and capped (30). The cap (30) and germanium layer (26) are partially removed so as to expose a silicon region (32) and leave a stack (31) of oxide, germanium, and capping layer on the silicon. Selective silicon is grown over the exposed silicon region. Silicon devices (36) are made in the selectively grown region of silicon (34). The remaining capping layer (30) is etched away to expose the thin layer of germanium (26). GaAs (38) is grown on the thin germanium layer (26), and GaAs devices (29) are built which can interoperate with the silicon devices (36). Alternatively, a smaller portion of the remaining cap (30) can be removed and germanium or silicon-germanium can be selectively grown on the exposed germanium (214) in order to form germanium or silicon-germanium devices (216). The smaller remaining cap can subsequently be removed to access the germanium and form GaAs devices (222) thereby allowing, GaAs, germanium-based, and silicon devices to co-exist.

### FIELD OF THE INVENTION

This invention relates generally to semiconductor structures, and more specifically to the monolithic integration and coexistence of mixed material systems, such as gallium arsenide on silicon.

### BACKGROUND OF THE INVENTION

Semiconductor devices often include multiple layers of conductive, insulating, and semiconductive layers. Often, the desirable properties of such layers improve with the crystallinity of the layer. For example, the electron mobility and electron lifetime of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monolithic thin films on a foreign substrate such as silicon (Si). To achieve optimal characteristics of the various monolithic layers, however, a monocrystalline film of high crystalline quality is desired. Attempts have been made, for example, to grow various monocrystalline layers on a substrate such as germanium, silicon, and various insulators. These attempts have generally been unsuccessful because lattice and thermal mismatches between the host crystal and the grown crystal have caused the resulting layer of monocrystalline material to be of low crystalline quality.

Many bodies of work discuss direct growth of GaAs on Si. In one traditional approach, germanium is grown on silicon and then GaAs is grown on the germanium. However, the germanium layer and subsequent GaAs layer have not been of good enough quality and have been too thick to allow efficient heterogeneous integration (hetero-integration for short) of devices. The term hetero-integration for the purposes of this application means the monolithically integrated coexistence of mixed material systems on a common substrate. Hetero-integration thus provides the ability to integrate multiple material based technologies (and therefore devices) in a single semiconductor structure.

Accordingly, a need exists for a semiconductor structure having improved monolithic integration of GaAs (and other compound semiconductors) and silicon. Such a semiconductor structure would enable high performance, low power, RF, analog, digital, and optical sub-systems, as well as allow for hetero-integration of systems formed by interconnecting these sub-systems.

### BRIEF DESCRIPTION OF THE DRAWINGS

The present invention is illustrated by way of example and not limitation in the accompanying figures, in which like references indicate similar elements, and in which:

FIGS. 1-11 illustrate, in cross section, a device structure in various stages of being formed in accordance with the present invention;

FIG. 12 is a flowchart in accordance with the present invention;

FIGS. 13-19 illustrates, in cross section, a device structure in various stages of development in accordance with an alternative embodiment of the invention;

FIGS. 20-25 illustrates, in cross section, the formation of the device structure further including a P+ buried layer as part of a further alternative embodiment of the invention;

FIGS. 26-27 illustrate, in cross section, further developmental stages of FIG. 25 including selective GaAs growth;

FIGS. 28 and 29 illustrate the further development of the structure of FIG. 25 including non-selective GaAs growth;

FIG. 30 shows GaAs devices formed in either of the structures of FIG. 27 or 29;

FIG. 31 illustrates the interconnect between GaAs and silicon devices for these structure of FIG. 30; FIGS. 32 and 33 illustrate cross sectional views of structures in accordance with the present invention; and

FIG. 34 is a flowchart in accordance with yet another alternative embodiment of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE DRAWINGS

In accordance with the present invention, there will be described herein a hetero-integrated structure and method of forming same in which a high quality compound semiconductor material, such as high quality gallium arsenide (GaAs), is grown over a thin germanium layer to co-exist with silicon for hetero-integration of devices. Briefly, a bonded germanium wafer of silicon, oxide, and germanium is formed and capped. The cap and germanium layer are partially removed so as to expose a silicon region and leave a stack of oxide, germanium, and capping layer on the silicon. Silicon is grown over the exposed silicon region. Silicon devices are made in the grown region of silicon. The remaining capping layer is etched away to expose the thin layer of germanium. GaAs is grown on the thin germanium layer, and GaAs devices are built which can interoperate with the silicon devices. Alternatively, a smaller portion of the remaining cap can be removed and germanium or silicon-germanium can be grown on the exposed germanium in order to form germanium or silicon-germanium devices. The smaller remaining cap can subsequently be removed to access the germanium and form GaAs devices thereby allowing, GaAs, germanium-based, and silicon devices to co-exist.

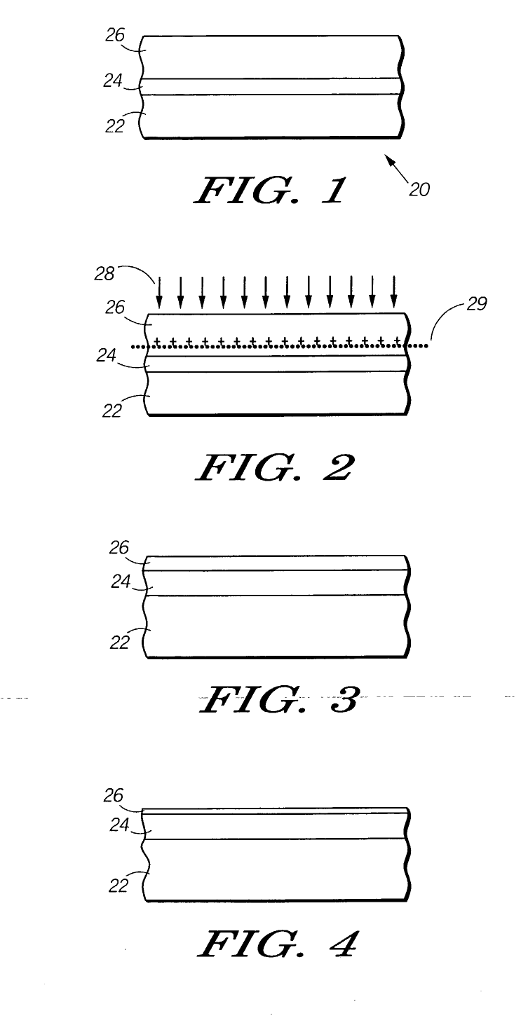

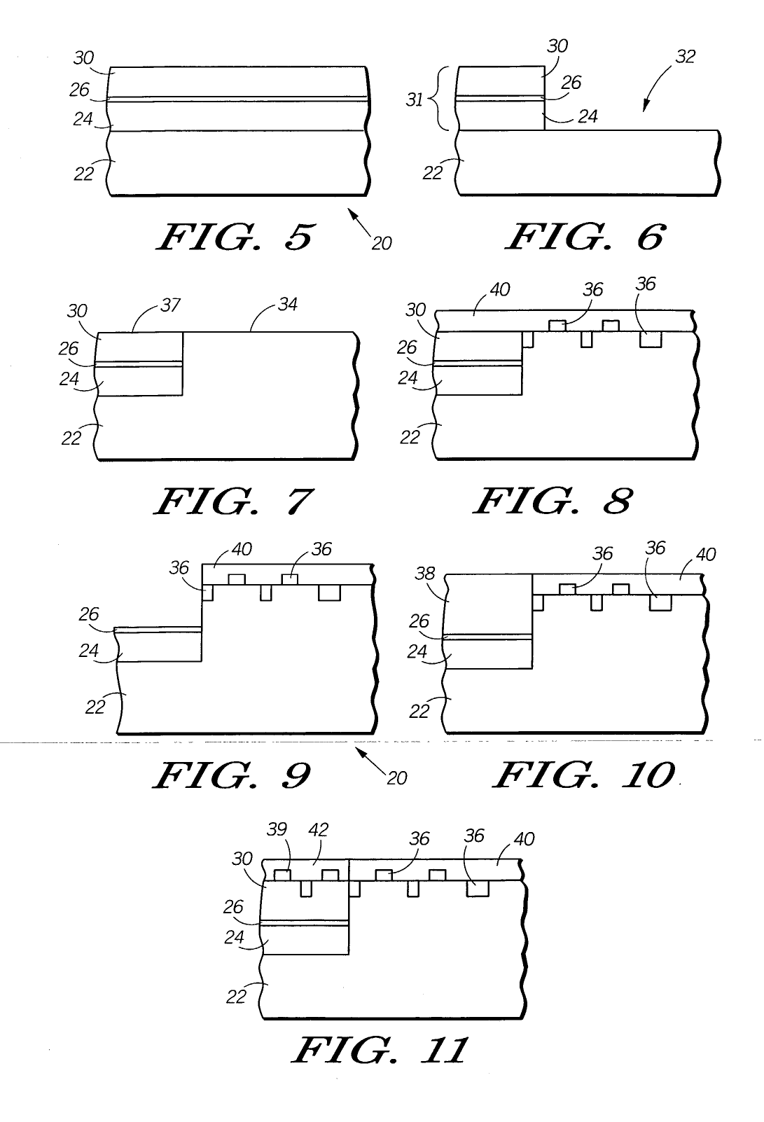

FIGS. 1-11 illustrate, in cross section, a device structure 20 in various stages of being formed in accordance with the present invention. While the present invention is described in terms of a GaAs on silicon example, other compound semiconductors, such as AlGaAs, InGaAs, InP, and GaN, can also benefit from this approach. FIGS. 1-4 represent the formation stages of a wafer having germanium on oxide on a silicon substrate. FIG. 5 represents a protection stage for the germanium layer. FIGS. 6-8 represent the stages for forming silicon devices. FIGS. 9-10 represent the stages for forming GaAs devices.

Referring now to FIG. 1, there is shown in cross section, a structure 20 of a silicon wafer 22 having oxide layer 24 and germanium layer 26. Layers 22, 24, and 26 are preferably wafer bonded to each other. FIG. 2 shows hydrogen being implanted 28 into the germanium layer 26. The purpose of the infusion of hydrogen into the germanium layer 26 is to separate the bonded Ge layer as indicated by designator 29 which will assist in thinning the Ge layer. FIG. 3 shows the germanium layer 26 having been cut down to achieve a thin Ge layer of preferably less than one-micron thickness. Various cutting and planarization techniques known in the art can be used to achieve the desired thickness. FIG. 4 shows the germanium layer 26 having been polished, preferably by chemical mechanical polish (CMP) techniques, to achieve an even thinner layer of germanium of preferably less than half-micron thickness. The purpose of development stages described in FIGS. 1-4 is to achieve a wafer of germanium on oxide on silicon substrate. While a preferred development technique has been described other techniques can be used to achieve this structure as well.

FIG. 5 shows a protection layer 30 deposited over the thin layer of germanium 26, in accordance with the present invention. Protection layer 30 is preferably formed of oxide material but can also be nitride, oxy-nitride, or similar dielectrics. Deposition techniques such as sputtering, CVD, ALD, MOCVD, as well as other techniques can be used to accomplish the deposition of the protection layer 30 over the thin germanium layer 26. In accordance with the present invention, the protection layer 30 operates as a capping layer and will also be referred to as capping layer 30. Thus, a bonded wafer of silicon 22, oxide 24, and germanium 26 is formed and capped 30, as shown in FIG. 5.

The capping layer 30, germanium layer 26, and oxide layer 24 are partially removed so as to expose a silicon region 32 and leave a stack 31 of oxide 24, germanium 26, and capping layer 30 on the silicon substrate 22. FIG. 6 shows an exposed silicon region 32 that is achieved by etching through a portion of the cap, germanium, and oxide layers 30, 26, and 24. Selective silicon growth is performed on the exposed silicon region 32 forming a plane of silicon 34 adjacent to top surface 37 of cap layer 30 as seen in FIG. 7. Silicon growth is accomplished through known chemical vapor deposition (CVD) and ultra high vacuum chemical vapor deposition (UHVCVD) techniques. Although not shown, the silicon growth process can also be accomplished using epitaxial over-growth techniques in which the silicon is overgrown higher than the cap layer 30 and then cut back or planarized to align with the cap surface 37. Epitaxial over-growth techniques of silicon will allow for undesirable crystal facets to be removed as will be described in conjunction with a further embodiment later on. Likewise, non-selective growth techniques of GaAs will also be described in conjunction with a further embodiment.

In FIG. 8, silicon devices 36 are formed on the silicon surface 34. Silicon devices 36, while shown in the figure as a MOSFET, can be a resistor, a capacitor, an active semiconductor component such as a diode or a transistor or an integrated circuit such as a CMOS integrated circuit. For example, silicon devices 36 can comprise a CMOS integrated circuit configured to perform digital signal processing or another function for which silicon integrated circuits are well suited. The electrical semiconductor component formed on the silicon surface 34 can be formed by conventional semiconductor processing as well known and widely practiced in the semiconductor industry. A layer of insulating material 40 such as a layer of silicon dioxide or the like may overlie electrical semiconductor component 36.

As seen in FIG. 8, an additional layer of dielectric 40 is deposited and planarized over the silicon surface 34 and cap surface 37 so that silicon devices 36 can be prepared for contact metallization. The dielectric capping layer 30 protects the layer of germanium layer 26 during the formation of the silicon devices 36.

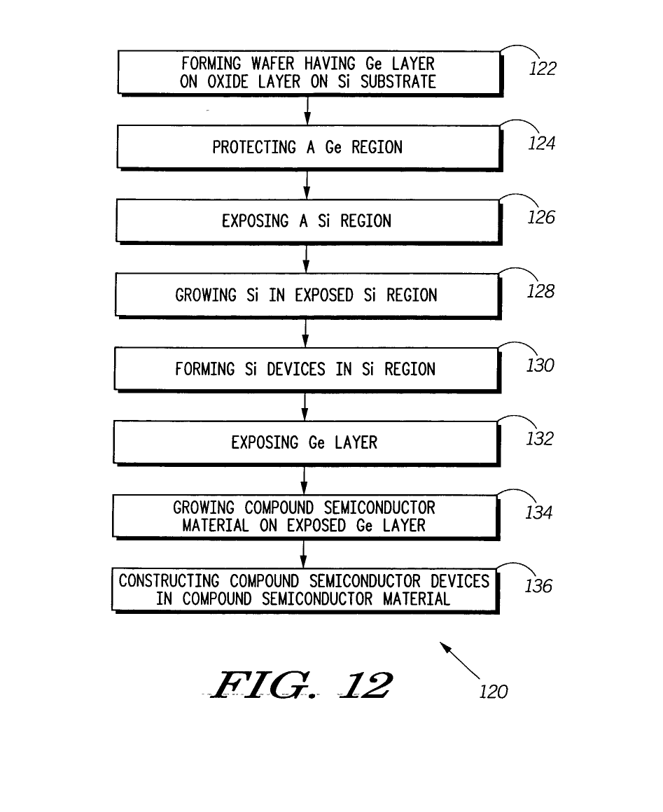

In accordance with the present invention, FIG. 9 shows structure 20 having been etched down to expose the thin germanium layer 26. A GaAs layer 38 is then grown over the exposed germanium layer 26 such that the GaAs layer 38 and silicon layer 40 are now co-planar. The GaAs layer 38 can be grown with molecular beam epitaxy (MBE) techniques. The process can also be carried out by the process of chemical vapor deposition (CVD), ultra-high vacuum chemical vapor deposition (UHVCVD), metal organic chemical vapor deposition (MOCVD), migration enhanced epitaxy (MEE), atomic layer epitaxy (ALE), or the like. Since GaAs is lattice matched to germanium, very high quality GaAs layers are possible without having to grow a very thick GaAs layer. Thicknesses of GaAs in the 100 to 10000 angstroms range are now possible. Alternate III-V compounds such as AlGaAs, InGaAs, InGaAlP, InGaAsN can be included as part of the epitaxial layer to form a variety of devices. GaAs semiconductor devices are then formed on the GaAs layer 38 as shown in FIG. 11. GaAs Semiconductor devices can be formed by processing steps conventionally used in the fabrication of gallium arsenide or other III-V compound semiconductor material devices. While a GaAs MESFET is shown in the figure, semiconductor devices can be any active or passive component, and preferably is a semiconductor laser, light emitting diode, photodetector, heterojunction bipolar transistor (HBT), high frequency MESFETs and High Electron Mobility Transistors (HEMT)s, or other component that utilizes and takes advantage of the physical properties of compound semiconductor materials. The GaAs device implemented in the GaAs layer 38 depends on the epitaxial layer design used to form the GaAs layer 38. An additional layer of dielectric 42 is deposited and planarized over the GaAs 38 and GaAs devices 39 so that the GaAs devices can be prepared for contact metallization. The growth of GaAs can be selective or non selective. (An alternative embodiment to be described later on will discuss non-selective GaAs growth in greater detail.) Thus, the co-existence of GaAs and Si and GaAs and Si devices is now possible.

FIG. 12 is a flowchart 120 summarizing the steps of forming a hetero-integrated semiconductor structure in accordance with the present invention. The process begins at step 122 by forming a wafer having a germanium layer on an oxide layer on a silicon substrate. The next few steps include protecting a germanium region at step 124, followed by exposing a silicon region at step 126 and growing silicon in the exposed silicon region at step 128. Forming silicon devices in the silicon region occurs at step 130. Then, by performing the steps of exposing the germanium layer at step 132 and growing compound semiconductor material on the exposed germanium layer at step 134, this allows for constructing compound semiconductor devices in the compound semiconductor material at step 136. Thus, a hetero-integrated structure of Si and GaAs having Si and GaAs devices has been formed, the interconnection of the devices will be described in a later embodiment.

As preferred techniques, step 122 of forming the wafer having the germanium layer on the oxide layer on the silicon substrate is preferably performed by wafer bonding. Step 124 of protecting the germanium region is preferably achieved by capping the region with silicon di-oxide and using silicon nitride spacers for side protection (to be described in a later). Growing the silicon at step 128 is preferably achieved by selective growth techniques, but non-selective growth techniques can be used as well. A P+ buried layer (also to be described later) can be implanted prior to silicon growth to provide for a low resistivity silicon region in selected parts of the silicon wafer, if desired.

FIGS. 13-19 illustrates, in cross section, a device structure in various stages of development in accordance with an alternative embodiment of the invention in which sidewall spacers are used. Like reference numerals have been be carried forward where appropriate.

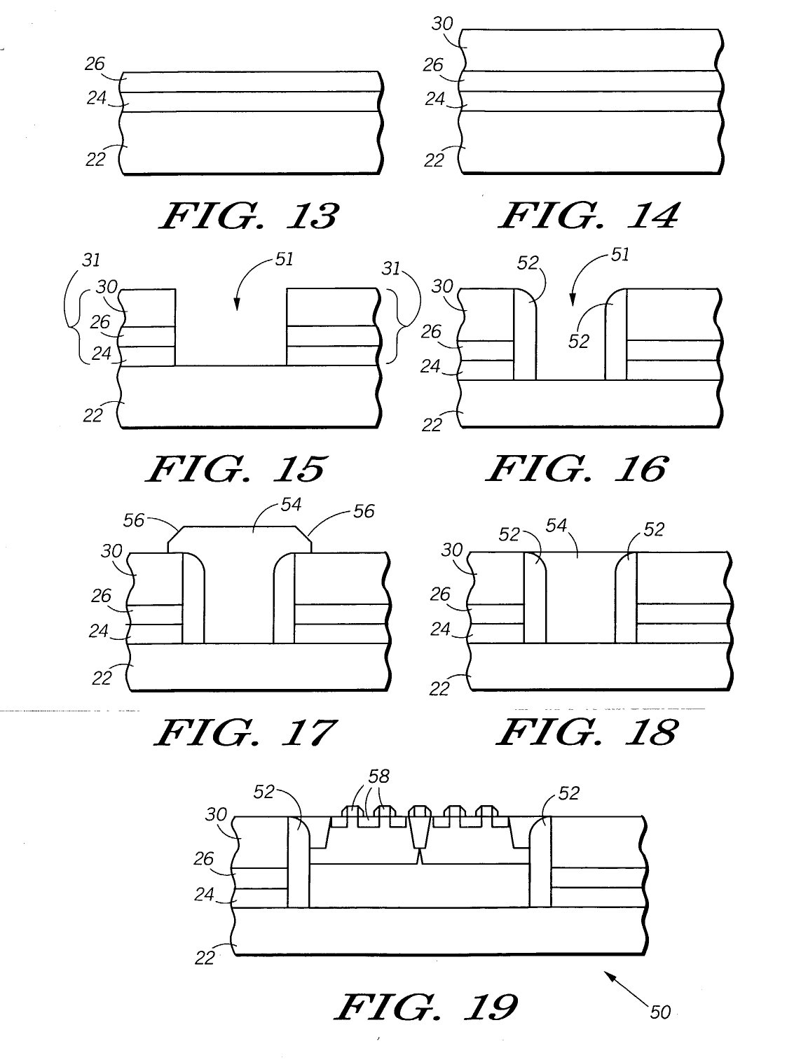

FIG. 13 starts with the formation of the thin germanium layer 26 on the oxide layer 24, on the silicon substrate 22 (like that obtained by the completion of development stage of FIG. 4 or other appropriate means). In FIG. 14, the structure is shown to further include cap layer 30. FIG. 15, shows a portion of the capping, germanium, and oxide layers 30, 26, 24 removed to form a well or trench 51 between two stacks 31. Well known techniques such as photoresist masking and plasma etching can be used to form the trench 51. FIG. 16 shows the addition of spacer material 52 on the inner sidewalls of the trench 51. The spacers 52 are preferably either an oxide or nitride material. FIG. 17 shows the selective growth of silicon material 54 within trench 51 and demonstrates how the silicon can tend to overgrow some of the capping layer 30 and form facets determined by crystal structure of silicon as indicated by designators 56. FIG. 18 shows the silicon after it has been planarized down to become substantially co-planar with the capping layer 30 of the stacks 31. FIG. 19 shows structure 50 in which silicon devices 58, such as CMOS devices, have been formed in the planarized silicon using conventional CMOS processing techniques. The silicon can also be used to make other silicon-based technologies and devices such as analog, RF, Bi-CMOS, and bipolar-based technologies.

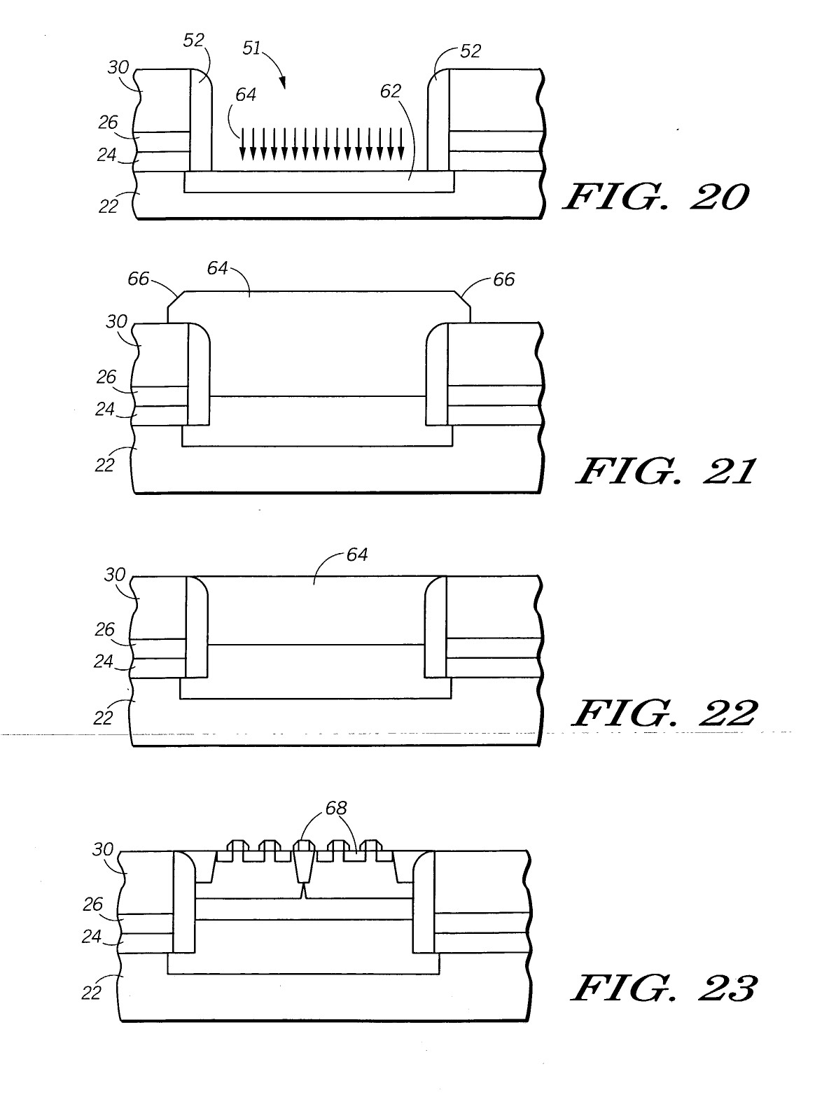

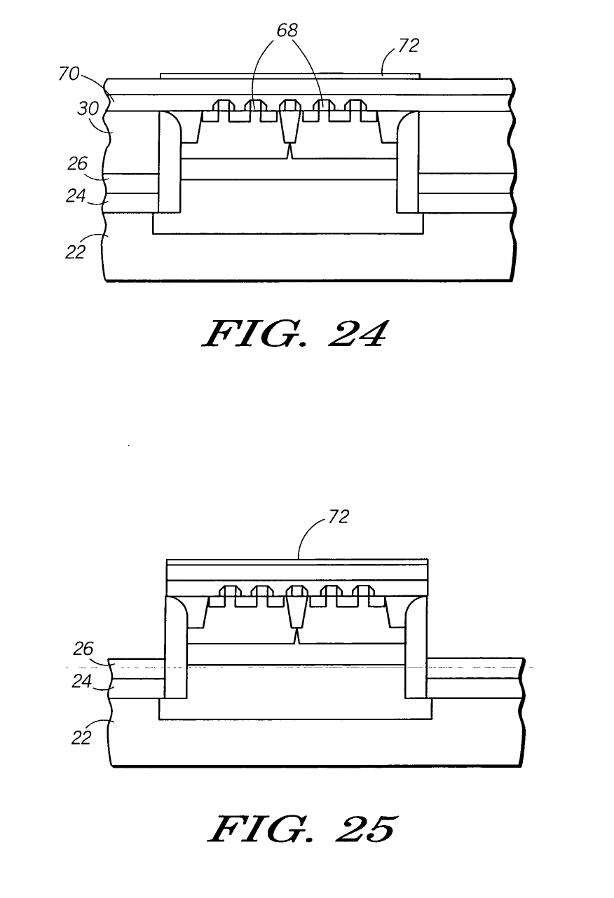

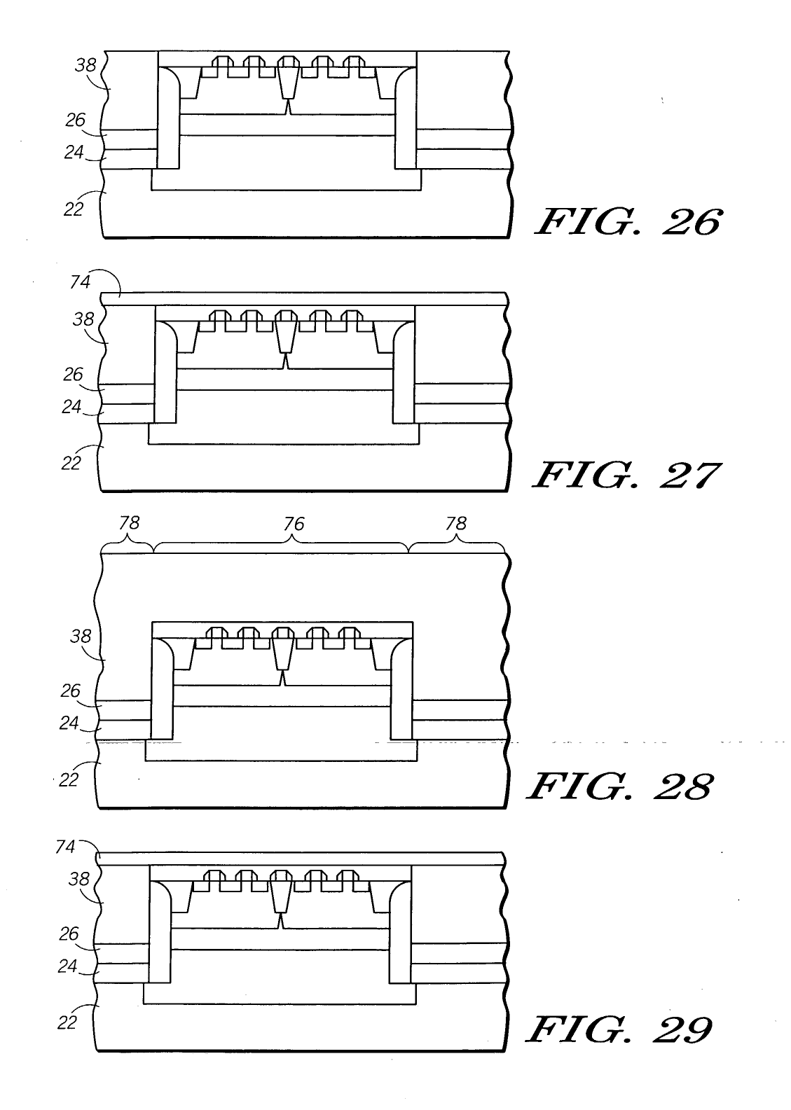

FIGS. 20-25 illustrates, in cross section, the formation of a device structure including a P+ buried layer as part of a further alternative embodiment of the invention. In FIG. 20, there is again shown the structure of FIG. 16, with germanium on oxide on silicon with trench 51, and side spacers 52. In addition, a P+ buried layer 60 is implanted into the silicon layer 22, preferably by the implantation of boron indicated by designator 62. The P+ buried layer 60 will provide a desired resistivity for future devices grown above it. Silicon material 64 is then grown over the P+ buried layer 60 as shown in FIG. 21. The selective growth of silicon material 64 can tend to overgrow the capping layers 30 and produce facets 66. FIG. 22 illustrates the silicon material 64 having been planarized such that the silicon material and capping layers 30 become substantially co-planar. Silicon devices 68, such as CMOS devices, or other silicon-based devices are formed in the planarized silicon 64 as shown in FIG. 23. These silicon devices will have been formed in regions of low resistivity, which can improve circuit performance in selected applications. FIG. 24 shows the addition of an oxide layer 70 planarized over the capping layers 30 and silicon devices 68, as well as the location of a masking region 72 over the silicon device region. FIG. 25 shows the structure with the planarized oxide layer 70 and the capping layer 30 removed. Thus, the structure is prepared for either selective or non-selective growth of GaAs as will be described with reference to FIGS. 26-29. The masking layers are typically removed prior to GaAs growth.

FIG. 26 shows how GaAs material 38 is selectively grown on the germanium layer 26. The mask 72 has been removed before the selective growth process of GaAs is completed. A capping layer 74 is then added as seen in FIG. 27 to cover the entire surface of the structure. This capping layer 74 can be a variety of materials including silicon nitride (SiN), silicon carbide (SiC) or aluminum nitride (AlN) to passivate the GaAs.

FIG. 28 shows how the non-selective growth of GaAs material over the germanium layer 26 results in GaAs overgrowth on non-Ge regions. However, the GaAs on non-Ge regions creates amorphous GaAs regions 76 while the GaAs on germanium creates crystalline GaAs regions 78. The GaAs in regions 76 and 78 are polished away or planarized using one of a variety of techniques, such as resist etch back, chemical mechanical polishing (CMP), or mask and etch techniques to become substantially co-planar with the silicon region. The structure is then covered with passivation layer 74 as shown in FIG. 29, and similar to that shown in FIG. 27. Thus, the two end structures of FIG. 27 and FIG. 29 are substantially similar whether they were formed with selective or non-selective growth techniques.

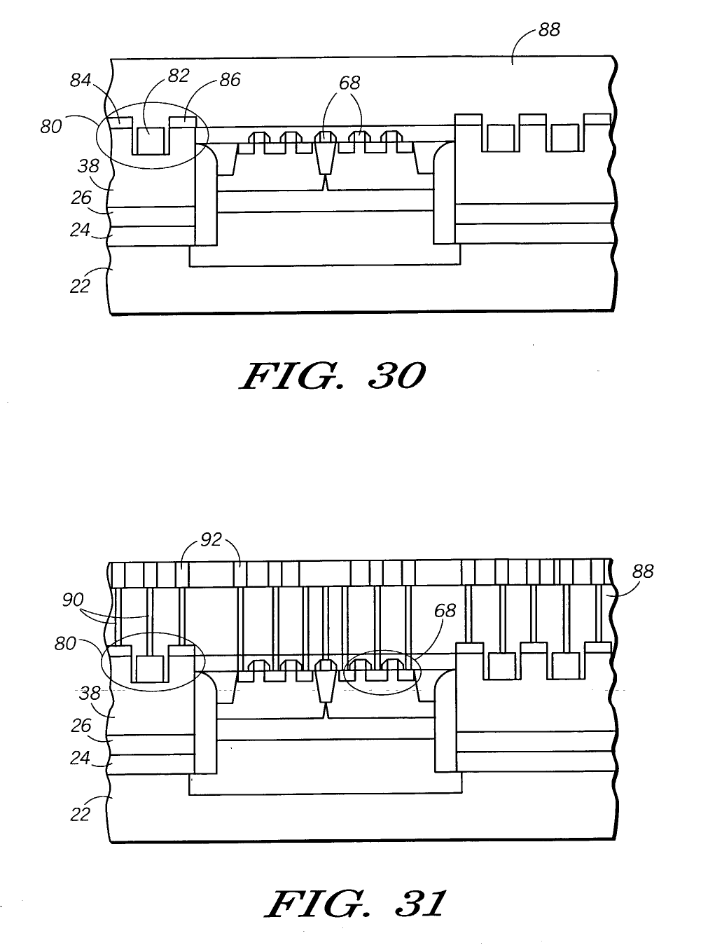

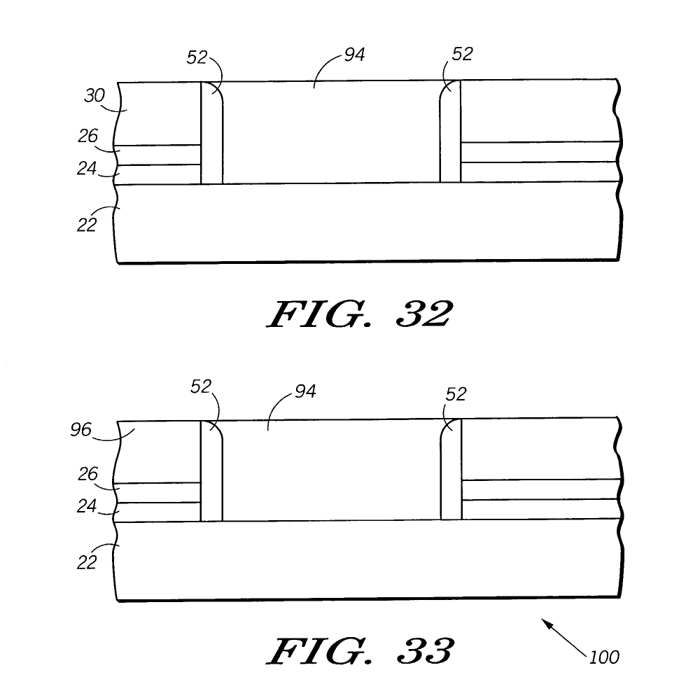

FIGS. 30 and 31 illustrate the implementation of GaAs devices 80 into the passivated structure. FIG. 30 shows the formation of MESFET or HEMT type devices with gate 82 and source/drain 84, 86. Other GaAs devices can be similarly formed in the GaAs regions of the wafer and is not limited to the formation of MESFETs or HEMTs. After devices have been built in both the silicon and GaAs regions, the entire wafer is covered with dielectric 88, such as nitride or oxide or oxide-nitride mixture, and planarized to prepare the surface for contact and metallization. As seen in FIG. 31, the contacts 90 are etched in the dielectric layer 88 to contact the necessary regions of the devices, both in the GaAs as well as the silicon regions. The contacts 90 are filled with conducting materials, and metal 92 is patterned on top to provide connectivity between the GaAs devices 80 and silicon devices 68. The details of contact formation and metallization are well understood by those familiar with the backend processing in the semiconductor industry.

Accordingly, high quality GaAs, and Si devices can all be formed over a common substrate in a single semiconductor structure through the use of a germanium inner layer.

Aside from the benefit of being able to form actual devices, the structures themselves can be used in a variety of applications in which islands of hetero-integrated materials are desired. The co-existence of silicon and GaAs islands through the use of germanium provides a useful structure because high quality GaAs and silicon coexistence can be achieved through the use of the bonded germanium wafers. FIGS. 32 and 33 provide first and second structures that in and of themselves are believed to be novel. FIG. 32 is a structure that can provide for the hetero-integrated structure of islands of silicon and island of some compound semiconductor over a silicon substrate. The structure includes a silicon substrate 22 having first and second stacks 31 with side spacers 52 forming a trench 51 filled with silicon 94 (grown either by selective or non-selective growth) between the stacks 31. The stacks 31 are formed of a capping layer 30, a germanium layer 26, and an oxide layer 24 formed over the silicon substrate 22. Thus, germanium is prepared for the subsequent growth of high quality compound semiconductors. Alternatively, the germanium can be grown to the level of the silicon for the creation of Ge based devices as well. Next, FIG. 33 shows the co-existence of silicon and GaAs by taking the structure of FIG. 33, removing the capping layer 30 and growing GaAs or other compound semiconductor 96. The use of the bonded germanium allows for high quality GaAs to be grown thus creating a useable high quality structure of hetero-integrated materials. While only two islands are shown in the figure, one each for silicon and GaAs, it is clear that the structure can be extended to include multiple silicon and GaAs islands separated by the spacer regions. Furthermore, islands of Ge or SiGe (for Ge-based devices like photodetectors) can also be created in like fashion.

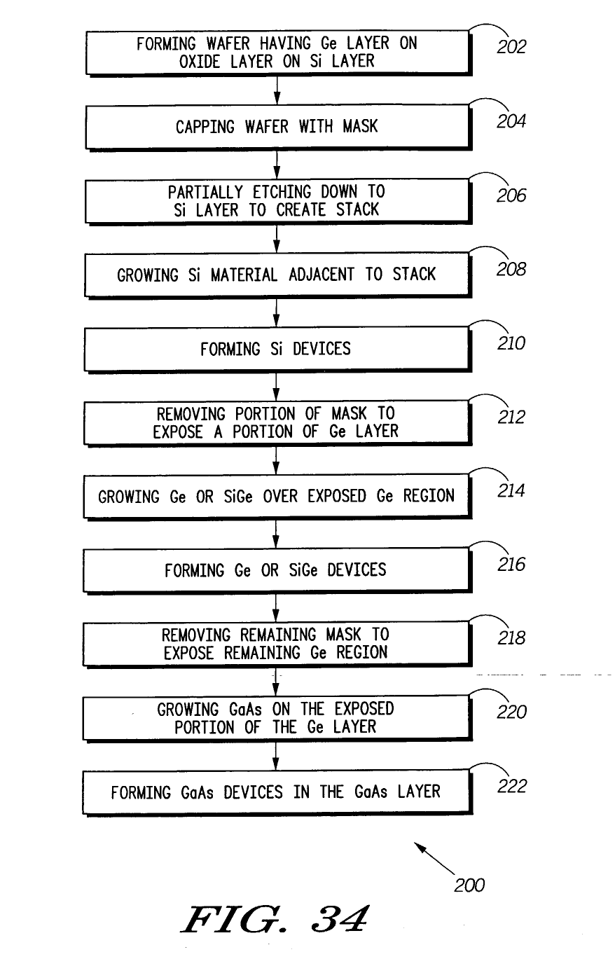

In accordance with another alternative embodiment, the coexistence of GaAs (or other compound semiconductor), germanium, and silicon can be achieved by totally encapsulating the germanium with side wall spacers (in a similar manner to that described previously for Si encapsulation) and then capping and etching down to the portion of the germanium contained within the spacers, and then growing the germanium up to the level of the silicon and GaAs surfaces. A flow chart 200 is provided in FIG. 34 to describe the formation of devices in each of the Si, Ge, and GaAs regions. Interconnections can be provided by the techniques already described in the GaAs/Si embodiments.

FIG. 34 is a flowchart 200 of a method of forming the hetero-integrated semiconductor structure in accordance with the alternative embodiment in which GaAs, Si, and Ge devices are formed and co-exist. The initial steps involve the creation of the base structure (steps 202, 204) followed by the formation of silicon devices (steps 206-210), followed by the formation of germanium devices (steps 212-216), and finally the formation of GaAs devices (steps 218-222).

Flowchart 200 begins with the step of forming a germanium wafer having germanium, oxide, and silicon layers at step 202, followed by the step of capping the wafer with a mask at step 204. Then, by partially etching the wafer down to the silicon layer so as to create a stack on top of the silicon at step 206 and growing silicon material adjacent to the stack(s) at step 208, the silicon devices can be formed in the silicon material at step 210.

The next few steps involve the creation of germanium devices. These steps include removing a portion of the mask to expose a portion of the germanium layer at step 212, growing germanium or silicon germanium over the exposed germanium region at step 214, and forming germanium or silicon-germanium devices in the region at step 216.

The remaining steps involve the formation of GaAs devices. These steps include removing the remaining mask to expose the remaining germanium region at step 218, growing gallium arsenide on the exposed portion of the germanium layer at step 220, and forming gallium arsenide devices in the GaAs layer at step 222. Accordingly, the method provided by the alternative embodiment provides for extended hetero-integration of Si, Ge, and GaAs. As explained earlier gallium arsenide is the preferred compound semiconductor material, but other III-V or II-IV compound semiconductor materials, as previously mentioned, can also be used.

Accordingly, high quality GaAs on thin epilayers on silicon has been achieved. This enhances the ability to create hetero-integrated systems such as optical integration with CMOS, GaAs RF and analog with CMOS digital, and SiGe bipolar with GaAs optical and electronic to name but a few. The structures and techniques formed in accordance with the present invention and alternative embodiments provide for the coexistence of islands of silicon and high quality III-V and II-IV compound semiconductors, such as GaAs. Islands of silicon, GaAs, and germanium are also possible along with the interconnectivity of devices in these different materials.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

We claim:

1. A semiconductor structure, comprising:
a silicon substrate having first and second portions;
an oxide layer overlying the first portion of the silicon substrate;
a germanium layer overlying the oxide layer;
a gallium arsenide layer overlying the germanium layer;
silicon (Si) material overlying the second portion of the silicon substrate; and
semiconductor devices formed in the silicon material and the gallium arsenide (GaAs) layer.

2. The structure of claim 1, wherein the silicon material and the gallium arsenide layer are substantially co-planar, and wherein planarization is used to achieve planarity of the GaAs layer and Si material.

3. The structure of claim 1, further comprising conductive contacts formed between semiconductors in the GaAs layer and Si material.

4. The structure of claim 1, wherein a P+ buried layer is implanted at least partially into the silicon substrate prior to Si material growth to provide a low resistivity silicon region.

5. A method of forming a hetero-integrated semiconductor device, comprising the steps of:
forming a wafer having a germanium (Ge) layer, an oxide layer, on a silicon (Si) substrate;
protecting a germanium region of the Ge layer;
exposing a silicon region of the Si substrate;
growing silicon material in the exposed silicon region;
forming silicon devices in the exposed silicon region; exposing a portion of the Ge layer; and
growing compound semiconductor material on the exposed portion of the Ge layer; and
constructing compound semiconductor devices in the compound semiconductor material.

6. The method of claim 5, wherein the step of forming the germanium-on-oxide-on-silicon wafer comprises wafer bonding.

7. The method of claim 5, wherein the step of protecting a germanium region comprises the steps of capping the germanium layer with oxide or nitride or oxide-nitride mixture and providing side protection with spacers.

8. The method of claim 5, wherein the step of growing silicon material comprises growing the silicon using a selective growth technique.

9. The method of claim 5, wherein the step of growing silicon material comprises growing the silicon using a non-selective growth technique.

10. The method of claim 5, wherein the compound semiconductor material comprises gallium arsenide (GaAs).

11. A method of forming a hetero-integrated semiconductor device, comprising the steps of:
forming a bonded wafer having germanium, oxide, and silicon layers;
capping the germanium layer with a nitride layer;
etching a portion of the capped layer, the germanium layer, and the oxide layer so as form an exposed silicon region;
selectively growing silicon over the exposed silicon region up to the capped layer;
forming silicon devices in the selectively grown silicon;
etching down the capped layer to expose the germanium layer;
growing GaAs on the germanium layer up to the selectively grown silicon; and
forming GaAs devices in the GaAs layer.

12. The method of claim 11, further comprising, between the steps of providing and capping, the steps of:
thinning the germanium layer; and
polishing the thinned germanium layer.

13. The method of claim 12, wherein the method of thinning the germanium layer includes the step of implanting hydrogen into the germanium layer at a predetermined depth.

14. The method of claim 11, further comprising, between the steps of etching a portion and selectively growing, the step of forming spacers next the germanium region for isolation.

15. A method of forming a hetero-integrated semiconductor structure, comprising:
forming a germanium wafer having germanium, oxide, and silicon layers; capping the wafer with a mask;
partially etching the wafer down to the silicon layer so as to create a stack on top of the silicon;
growing silicon material adjacent to the stack;
forming silicon devices in the silicon material; removing a portion of the mask to expose a portion of the germanium layer;
growing germanium or silicon germanium over the exposed germanium region;
forming germanium or silicon-germanium devices in the grown germanium or silicon germanium;
removing the remaining mask to expose the remaining germanium region;
growing gallium arsenide on the exposed portion of the germanium layer; and
forming gallium arsenide devices in the GaAs layer.

16. The method of claim 15, wherein the mask is formed of an oxide or nitride or oxide nitride mixture layer.

17. A semiconductor structure, comprising:
a silicon substrate;
first and second stacks on the silicon substrate, each of the first and second stacks comprising a compound semiconductor layer over a germanium layer over an oxide layer, the oxide layer being formed on the silicon substrate;
side spacers adjacent to the first and second stacks; and
silicon material filled between the side spacers of the first and second stacks.

18. The semiconductor of claim 17, wherein the compound semiconductor layer comprises one of: GaAs, AlGaAs, InGaAs, InP, and GaN.

19. The semiconductor of claim 17, wherein semiconductor devices are formed in the silicon material and the compound semiconductor material.

20. The semiconductor of claim 19, wherein semiconductor devices in the silicon material are interconnected to the semiconductor devices in the compound semiconductor material.

21. The semiconductor of claim 17, providing for coexistence of islands of silicon and compound semiconductor.

22. A semiconductor structure, comprising:
a silicon substrate;
first and second stacks on the silicon substrate, the first stack comprising a compound semiconductor material over a germanium layer over an oxide layer, the oxide layer being formed on the silicon substrate, the second stack comprising a germanium material over an oxide layer, the oxide layer being formed on the silicon substrate;
side spacers adjacent to the first and second stacks; and
silicon material filled between the side spacers of the first and second stacks.

23. The semiconductor structure of claim 22, wherein the compound semiconductor material comprises one of: GaAs, InGaAs, AlGaAs, InP, and GaN.

24. The semiconductor structure of claim 22, further comprising semiconductor devices formed in the silicon material, the germanium material, and the compound semiconductor material.

25. The semiconductor structure of claim 23, wherein the semiconductor devices in the silicon material, the compound semiconductor material, and the germanium material are all interconnected.

26. The semiconductor of claim 22, providing for coexistence of islands of silicon material, germanium material, and compound semiconductor material.

27. A semiconductor structure, comprising:
a silicon substrate; and
first and second stacks on the silicon substrate, the first stack comprising a compound semiconductor material over a germanium layer over an oxide layer, the oxide layer being formed on the silicon substrate, the second stack comprising silicon layer grown on the silicon substrate and formed adjacent to the compound semiconductor.

28. A semiconductor structure, comprising:
a silicon substrate;
first and second stacks on the silicon substrate, the first stack comprising a first compound semiconductor material over a germanium layer over an oxide layer, the oxide layer being formed on the silicon substrate, the second stack comprising a second compound semiconductor material over the germanium layer over the oxide layer,
side spacers adjacent to the first and second stacks; and
silicon material filled between the side spacers of the first and second stacks.

29. The semiconductor structure of claim 28, wherein the first and second compound semiconductor materials are different from each other.

30. A method of forming a hetero-integrated semiconductor structure, comprising:
forming a germanium wafer having germanium, oxide, and silicon layers;
capping the wafer with a protective dielectric capping layer;
patterning a mask on the wafer to expose selected regions;
partially etching the wafer in the selected regions down to the silicon layer so as to create a stack on top of the silicon;
growing silicon material adjacent to the stack; forming silicon devices in the silicon material;
forming a second mask to expose a portion of the capping layer to expose the germanium layer;
growing germanium or silicon germanium over the exposed germanium region;
forming germanium or silicon-germanium devices in the grown germanium or silicon germanium;
forming a third mask to expose the remaining capping layer and exposing the germanium region;
growing gallium arsenide on the exposed portion of the germanium layer; and forming gallium arsenide devices in the GaAs layer.

31. The method of claim 26, wherein the capping layer is formed of a nitride layer.
